(19) United States
(12) Patent Application Publication
(10) Pub. No.: US 2026/0089993 A1
(43) Pub. Date: Mar. 26, 2026

(54) SEMICONDUCTOR DEVICE GATE STRUCTURE AND RELATED METHODS

(71) Applicant: Taiwan Semiconductor Manufacturing Company, Ltd., Hsinchu (TW)

(72) Inventors: Yu-Cheng Shiau, Hsinchu (TW); Wei Liu, Kaohsiung City (TW); Cheng-Wei Chang, Hsinchu (TW); Chao-Hui Liu, Hsinchu (TW); Yu-Ting Ciou, Hsinchu City (TW); Chih-Tang Peng, Hsinchu County (TW); Tai-Chun Huang, Hsin-Chu City (TW); Tze-Liang Lee, Hsinchu (TW)

(21) Appl. No.: 18/891,311

(22) Filed: Sep. 20, 2024

(51) Int. Cl. H01L 29/66; H01L 21/02; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018; H10P 14/6319

(57) ABSTRACT

Methods and structures for modulating a metal gate profile include providing a fin having an epitaxial layer stack with a plurality of semiconductor channel layers. A liner layer is deposited over surfaces of adjacent semiconductor channel layers of the plurality of semiconductor channel layers. A plasma treatment process is performed to the liner layer. A first portion of the plasma-treated liner layer is removed to form a gap between the adjacent semiconductor channel layers, while a second portion of the plasma-treated liner layer remains disposed on surfaces of the adjacent semiconductor channel layers. After removing the first portion of the plasma-treated liner layer, a gate structure is formed within the gap, where the gate structure has a convex shape or a concave shape.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

In general, GAA transistors may be implemented, for example, in cases where FinFETs can no longer meet performance requirements. However, fabrication of GAA transistors has introduced new challenges to the semiconductor manufacturing process and has led to associated device reliability concerns. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabricating a semiconductor device 300 according to one or more aspects of the present disclosure;

FIGS. 3, 4, 5, 7, 8, 9, 10, 11, and 12 provide cross-sectional views of an embodiment of the semiconductor device 300 along a plane substantially parallel to a plane defined by section AA′ of FIG. 1, in accordance with some embodiments;

FIGS. 5A, 6A, 7A, 8A, 9A, 11A, 12A, 13A, and 14A provide enlarged views of a portion of the semiconductor device 300, in accordance with some embodiments of the present disclosure;

and

FIGS. 5B, 6B, 7B, 8B, 9B, 11B, 12B, 13B, and 14B provide enlarged views of the portion of the semiconductor device 300, in accordance with other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/−10% of the recited value or between compared values. For instance, if dimension A is described as being “substantially equal” to dimension B, it will be understood that dimension A is within +/−10% of dimension B. As another example, if a layer is described as having a thickness of about 100 nm, it will be understood that the thickness of the layer may in a range between 90-110 nm.

It is also noted that the present disclosure presents embodiments in the form of multi-gate transistors. Multi-gate transistors include those transistors whose gate structures are formed on at least two-sides of a channel region. These multi-gate devices may include a P-type transistor or an N-type transistor. Specific examples may be presented and referred to herein as FinFETs, on account of their fin-like structure. Also presented herein are embodiments of a type of multi-gate transistor referred to as a gate-all-around (GAA) transistor. A GAA transistor includes any device that has its gate structure, or portion thereof, formed on 4-sides of a channel region (e.g., surrounding a portion of a channel region). Devices presented herein also include embodiments that have channel regions disposed in semiconductor channel layers. In various embodiments, the semiconductor channel layers may include nanosheet channel(s), nanowire channel(s), bar-shaped channel(s), and/or other suitable channel configurations. Presented herein are embodiments of devices that may have one or more channel regions (e.g., semiconductor channel layers) associated with a single, contiguous gate structure. However, one of ordinary skill would recognize that the teaching can apply to a single channel (e.g., single semiconductor channel layer) or any number of channels. One of ordinary skill may recognize other examples of semiconductor devices that may benefit from aspects of the present disclosure.

For multi-gate device, such as GAA devices, a metal gate profile (e.g., between adjacent semiconductor channel layers) is critical for both device performance and yield. In at least some existing implementations, options for modulating the metal gate profile remain limited, especially for highly-scaled devices. This can reduce device performance and cause reliability concerns. Recently, a disposable interposer process has been introduced, as part of a GAA device process flow, to improve device drive current, lower capacitance, and reduce short-channel effects. However, effective control of the metal gate profile implemented as part of the disposable interposer process has remained a challenge. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures for modulating a metal gate profile of a multi-gate device (e.g., such as a GAA device), to address various existing challenges. In various embodiments, the metal gate profile (e.g., between adjacent semiconductor channel layers) in a final device structure may have a convex shape or a concave shape. For example, the metal gate profile having the convex shape may have a greater thickness near a center of the metal gate disposed between center regions of adjacent semiconductor channel layers, and a lesser thickness near lateral ends of the metal gate disposed between lateral ends of the adjacent semiconductor channel layers. In another example, the metal gate profile having the concave shape may have a greater thickness near lateral ends of the metal gate disposed between lateral ends of the adjacent semiconductor channel layers, and a lesser thickness near a center of the metal gate disposed between center regions of adjacent semiconductor channel layers.

In some examples, a method of modulating the metal gate profile includes initially removing dummy layers (e.g., such as SiGe layers) that interpose adjacent semiconductor channel layers and re-depositing a liner layer and a disposable interposer layer (also referred to as “interposer layer”) to fill a cavity formed by removal of the dummy layers. The liner layer may, in some cases, include an ALD-deposited layer such as an oxide layer, a SiOC layer, or other suitable layer, and the selection of a particular composition of the liner layer may depend on whether a convex or concave shape is desired for the metal gate profile in the final device structure. After depositing the liner layer, and prior to depositing the interposer layer, a plasma process may be performed to treat the liner layer. For instance, if the liner layer includes an oxide layer, a nitrogen-based plasma process (e.g., using NH₃ or N₂ gas) may be performed to form nitrogen-rich regions within the oxide liner layer on portions of the oxide liner layer disposed over lateral end regions of the adjacent semiconductor channel layers. Formation of the nitrogen-rich regions may simultaneously provide or define low nitrogen concentration regions (or nitrogen-free regions) of the oxide liner layer disposed over central regions of the adjacent semiconductor channel layers. Moreover, a difference in nitrogen concentration between the nitrogen-rich regions and the low nitrogen concentration regions (or nitrogen-free regions) is sufficient to provide etch selectivity between the two regions, that is between the nitrogen-rich regions and the low nitrogen concentration regions (or nitrogen-free regions).

In another example, if the liner layer includes an SiOC layer, an oxygen-based plasma process (e.g., using O₂ gas) may be performed to form carbon-deficient regions within the SiOC liner layer on portions of the SiOC liner layer disposed over lateral end regions of the adjacent semiconductor channel layers. Formation of the carbon-deficient regions may simultaneously define higher carbon concentration regions of the SiOC liner layer (e.g., regions of the SiOC liner layer not substantially impacted by the oxygen-based plasma process) disposed over central regions of the adjacent semiconductor channel layers. Moreover, a difference in carbon concentration between the carbon-deficient regions and the higher carbon concentration regions is sufficient to provide etch selectivity between the two regions, that is between the carbon-deficient regions and the higher carbon concentration regions.

After performing the plasma treatment of the liner layer, the interposer layer may be deposited to fill the remaining space of the cavity formed by removal of the dummy layers. Thereafter, a recessing process is performed to recess the deposited liner layer and interposer layer to form inner spacer recesses between lateral ends of adjacent semiconductor channel layers. An inner spacer material is deposited within the inner spacer recesses and etched-back to complete formation of the inner spacers. After formation of the inner spacers, epitaxial source/drain features are formed. Thereafter, remaining portions of the interposer layer, as well as selected portions of the liner layer (as discussed below), are removed to form gaps between adjacent semiconductor channel layers within which a metal gate structure is subsequently formed.

In some embodiments, if the liner layer includes an oxide layer, removal of the portions of the interposer layer (e.g., such as by a wet etch process) also serves to remove the low nitrogen concentration regions (or nitrogen-free regions) of the oxide liner layer, while the nitrogen-rich regions of the oxide liner layer remain disposed over lateral end regions of the adjacent semiconductor channel layers. The nitrogen-rich regions of the oxide liner layer that remain, together with the adjacent semiconductor channel layers, serve to define a gap between the adjacent semiconductor channel layers having a concave shape. A metal gate structure may thus subsequently be formed within the gap, where the metal gate profile of the metal gate structure has a convex shape that is complementary to the concave shape of the gap.

In some embodiments, if the liner layer includes an SiOC layer, removal of the portions of the interposer layer (e.g., such as by a wet etch process) also serves to remove the carbon-deficient regions of the SiOC liner layer, while the higher carbon concentration regions of the SiOC liner layer (e.g., regions of the SiOC liner layer not substantially impacted by the oxygen-based plasma process) remain disposed over central regions of the adjacent semiconductor channel layers. The higher carbon concentration regions of the SiOC liner layer that remain, together with the adjacent semiconductor channel layers, serve to define a gap between the adjacent semiconductor channel layers having a convex shape. A metal gate structure may thus subsequently be formed within the gap, where the metal gate profile of the metal gate structure has a concave shape that is complementary to the convex shape of the gap. Embodiments of the present disclosure thus provide effective control of a metal gate profile implemented as part of a disposable interposer process, which can be tuned in accordance with device design and/or performance requirements. Other embodiments and advantages will be evident to those skilled in the art upon reading the present disclosure.

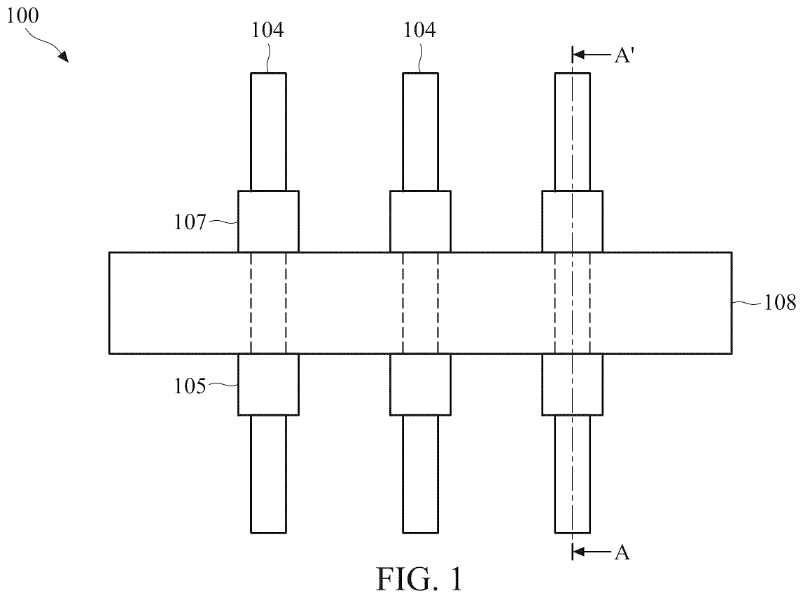

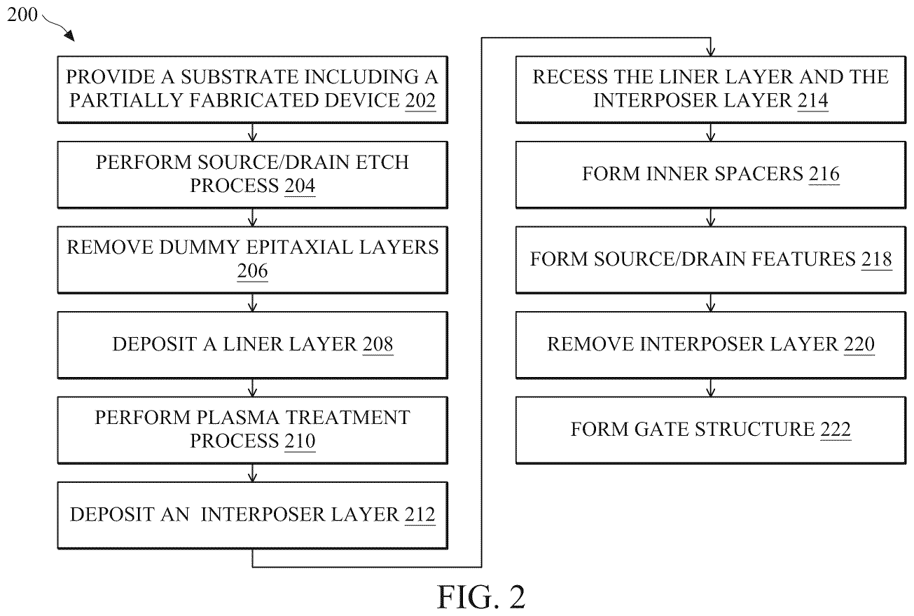

For purposes of the discussion that follows, FIG. 1 provides a simplified top-down layout view of a multi-gate device 100. In various embodiments, the multi-gate device 100 may include a FinFET device, a GAA transistor, or other type of multi-gate device. The multi-gate device 100 may include a plurality of fin elements 104 extending from a substrate, a gate structure 108 disposed over and around the fin elements 104, and source/drain regions 105, 107, where the source/drain regions 105, 107 are formed in, on, and/or surrounding the fins 104. A channel region of the multi-gate device 100, which may include a plurality of semiconductor channel layers (e.g., when the multi-gate device 100 includes a GAA transistor), is disposed within the fins 104, underlying the gate structure 108, along a plane substantially parallel to a plane defined by section AA′ of FIG. 1. In some embodiments, sidewall spacers may also be formed on sidewalls of the gate structure 108. Various other features of the multi-gate device 100 are discussed in more detail below with reference to the method of FIG. 2.

Referring to FIG. 2, illustrated therein is a method 200 of semiconductor fabrication including fabrication of a semiconductor device 300 (e.g., which includes a multi-gate device) with a metal gate structure having a metal gate profile with a convex shape or a concave shape, in accordance with various embodiments. The method 200 is discussed below with reference to fabrication of GAA transistors. However, it will be understood that aspects of the method 200 may be equally applied to other types of multi-gate devices, or to other types of devices implemented by the multi-gate devices, without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

It is further noted that, in some embodiments, the semiconductor device 300 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor device 300 may include a plurality of semiconductor devices (e.g., transistors) which may be interconnected. Moreover, it is noted that the process steps of method 200, including any descriptions given with reference to the figures are merely exemplary and are not intended to be limiting beyond what is specifically recited in the claims that follow.

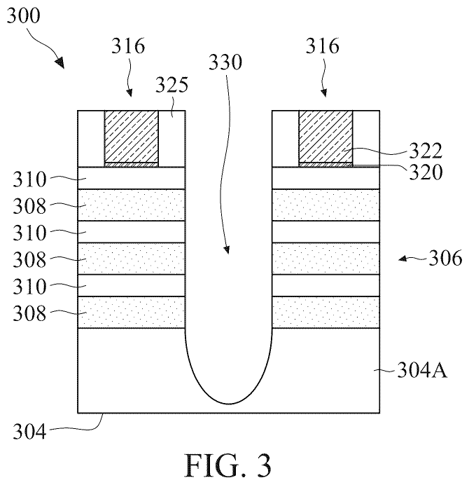

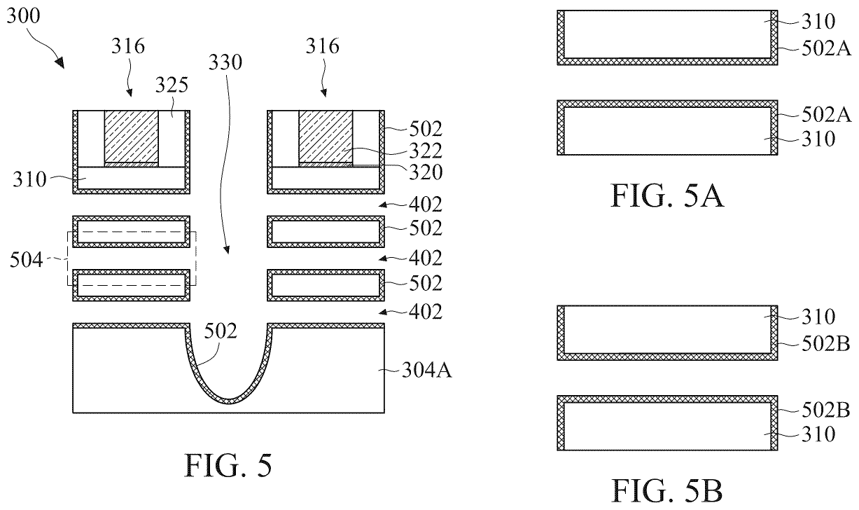

The method 200 begins at block 202 where a substrate including a partially fabricated device is provided. Referring to the example of FIG. 3, in an embodiment of block 202, a partially fabricated device 300 is provided. FIGS. 3-5 and 7-12 provide cross-sectional views of an embodiment of the semiconductor device 300 along a plane substantially parallel to a plane defined by section AA′ of FIG. 1 (e.g., along the direction of a fin 306). FIGS. 5A-9A and 11A-14A provide enlarged views of a portion 504 of the semiconductor device 300, in accordance with some embodiments of the present disclosure. FIGS. 5B-9B and 11B-14B provide enlarged views of the portion 504 of the semiconductor device 300, in accordance with other embodiments of the present disclosure.

The device 300 may be formed on a substrate 304. In some embodiments, the substrate 304 may be a semiconductor substrate such as a silicon substrate. The substrate 304 may include various layers, including conductive or insulating layers formed on a semiconductor substrate. The substrate 304 may include various doping configurations depending on design requirements as is known in the art. The substrate 304 may also include other semiconductors such as germanium, silicon carbide (SiC), silicon germanium (SiGe), or diamond. Alternatively, the substrate 304 may include a compound semiconductor and/or an alloy semiconductor. Further, the substrate 304 may optionally include an epitaxial layer (epi-layer), may be strained for performance enhancement, may include a silicon-on-insulator (SOI) structure, and/or have other suitable enhancement features.

As shown in FIG. 3, the device 300 includes a fin 306 having a substrate portion 304A (formed from the substrate 304), epitaxial layers 308 of a first composition and epitaxial layers 310 of a second composition that interpose the layers 308 of the first composition. In some cases, shallow trench isolation (STI) features may be formed to isolate the fin 306 from neighboring fins. For purposes of this discussion, the epitaxial layers 308 of the first composition include dummy layers, and the epitaxial layers 310 of the second composition include semiconductor channel layers. In an embodiment, the epitaxial layers 308 of the first composition include SiGe and the epitaxial layers of the second composition 310 include silicon (Si). It is also noted that while the layers 308, 310 are shown as having a particular stacking sequence within the fin 306, where the layer 310 is the topmost layer of the stack of layers 308, 310, other configurations are possible. For example, in some cases, the layer 308 may alternatively be the topmost layer of the stack of layers 308, 310. Stated another way, the order of growth for the layers 308, 310, and thus their stacking sequence, may be switched or otherwise be different than what is shown in the figures, while remaining within the scope of the present disclosure.

In various embodiments, the epitaxial layers 310 (e.g., including the second composition), or portions thereof, may form a channel region of a GAA transistor of the device 300. For example, the layers 310 may be referred to as semiconductor channel layers that are used to form a channel region of a GAA transistor. In various embodiments, the semiconductor channel layers (e.g., the layers 310 or portions thereof) may include nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the fin 306 is illustrated as including three (3) layers of the epitaxial layer 308 and three (3) layers of the epitaxial layer 310, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the GAA transistor. In some embodiments, the number of epitaxial layers 310, and thus the number of semiconductor channel layers, is between 3 and 10.

In some embodiments, the epitaxial layers 308 (the dummy layers) each have a thickness in a range of about 4-8 nanometers (nm). In some cases, the epitaxial layers 310 (the semiconductor channel layers) each have a thickness in a range of about 4-8 nm. As noted above, the epitaxial layers 310 may serve as channel region(s) for a subsequently formed multi-gate device (e.g., a GAA transistor) and its thickness may be chosen based at least in part on device performance considerations. The epitaxial layers 308 may serve to define a gap distance between adjacent channel region(s) for the subsequently formed multi-gate device and its thickness may also be chosen based at least in part on device performance considerations.

The device 300 further includes gate stacks 316 formed over the fin 306. In an embodiment, the gate stacks 316 are dummy (sacrificial) gate stacks that are subsequently removed and replaced by a final gate stack at a subsequent processing stage of the device 300. For example, the gate stacks 316 may be replaced at a later processing stage by a high-K dielectric layer (HK) and metal gate electrode (MG). While the present discussion is directed to a replacement gate (gate-last) process whereby a dummy gate structure is formed and subsequently replaced, other configurations may be possible (e.g., such as a gate-first process). The portion of the fin 306 underlying the gate stacks 316 may be referred to as the channel region of the device 300. The gate stacks 316 may also define source/drain regions of the fin 306, for example, the regions of the fin 306 adjacent to and on opposing sides of the channel region.

In some embodiments, the gate stacks 316 include a dielectric layer 320 and an electrode layer 322 over the dielectric layer 320. In some embodiments, the dielectric layer 320 includes silicon oxide. Alternatively, or additionally, the dielectric layer 320 may include silicon nitride, a high-K dielectric material or other suitable material. In some embodiments, the electrode layer 322 may include polycrystalline silicon (polysilicon). In some embodiments, and after formation of the gate stacks 316, one or more spacer layers 325 may be formed on sidewalls of the gate stacks 316. In some cases, the one or more spacer layers 325 may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. In some embodiments, the one or more spacer layers 325 include multiple layers, such as main spacer layers, liner layers, and the like.

The method 200 then proceeds to block 204 where a source/drain etch process is performed. Still with reference to FIG. 3, in an embodiment of block 204, a source/drain etch process is performed to the device 300. In some embodiments, the source/drain etch process is performed to remove the exposed epitaxial layers 308, 310 in source/drain regions of the device 300 to form a trench 330 which exposes an underlying portion of the substrate 304. The source/drain etch process also serves to expose lateral surfaces of the epitaxial layers 308, 310, as shown in FIG. 3. In some embodiments, the source/drain etch process may also remove portions of the one or more spacer layers 325. In some embodiments, the source/drain etch process may include a dry etching process, a wet etching process, and/or a combination thereof.

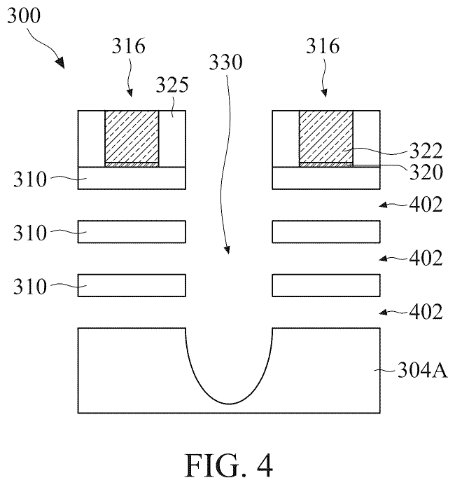

The method proceeds to block 206 where dummy epitaxial layers are removed. Referring to the example of FIGS. 3 and 4, in an embodiment of block 206, the dummy epitaxial layers (the epitaxial layers 308) are selectively removed (e.g., using a selective etching process), while the semiconductor channel layers (the epitaxial layers 310) remain unetched. To be sure, in various examples, the selective removal of the dummy epitaxial layers completely removes the epitaxial layers 308. The selective etching process may be performed through the trenches 330 provided by the source/drain etch process (block 204). In some embodiments, the selective etching process may include a selective wet etching process. In some cases, the selective wet etching includes ammonia (NH₃) and/or ozone (O₃). As merely one example, the selective wet etching process includes tetra-methyl ammonium hydroxide (TMAH). In some embodiments, the selective etching process may include a dry, plasma-free etching process. In some examples, the selective etching process may include etching using a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch. It is noted that as a result of the selective removal of the dummy epitaxial layers (the epitaxial layers 308), gaps (or cavities) 402 are formed between the adjacent semiconductor channel layers (the epitaxial layers 310). As shown, the gaps 402 expose surfaces of the semiconductor channel layers (the epitaxial layers 310). In particular, the gaps 402 expose a bottom surface of a topmost epitaxial layer 310, a top surface of the substrate portion 304A, and top and bottom surfaces of semiconductor channel layers (epitaxial layers 310) disposed between the topmost epitaxial layer 310 and the substrate portion 304A.

After removal of the dummy epitaxial layers (block 206), the method 200 then proceeds to block 208 where a liner layer is deposited. Referring to FIGS. 4 and 5/5A/5B, in an embodiment of block 208, a liner layer 502 is conformally deposited over the device 300 and within the trench 330 including along exposed surfaces of the trench 330. The liner layer 502 is also conformally deposited within the gaps (or cavities) 402 that were previously formed by removal of the dummy epitaxial layers (block 206) including along exposed surfaces of the gaps 402. For example, the liner layer 502 is deposited along sidewall surfaces of the one or more spacer layers 325, lateral surfaces of the semiconductor channel layers (the epitaxial layers 310), the bottom surface of a topmost epitaxial layer 310, a top surface of the substrate portion 304A, and top and bottom surfaces of semiconductor channel layers (epitaxial layers 310) disposed between the topmost epitaxial layer 310 and the substrate portion 304A. In some examples, the liner layer 502 may be said to wrap around (or surround) the exposed surfaces of the semiconductor channel layers (the epitaxial layers 310). In various embodiments, the liner layer 502 may include an oxide layer (e.g., such as SiO₂) or a carbon-containing layer (e.g., such as SiOC). In some examples, the liner layer 502 may include another dielectric material such as silicon carbide, a low-K material (e.g., with a dielectric constant ‘k’<7), or another suitable oxide layer or carbon-containing layer. In some cases, the liner layer 502 may be conformally deposited using an ALD process. Alternatively, the liner layer 502 may be deposited using a CVD process, a subatmospheric CVD (SACVD) process, a flowable CVD process, or other suitable process. A thickness of the liner layer 502, in some embodiments, may be in a range of between about 1-3 nm.

By way of illustration, FIGS. 5A and 5B provide enlarged views of a portion 504 of the semiconductor device 300 of FIG. 5, in accordance with various embodiments of the present disclosure. In particular, the portion 504 illustrates a pair of adjacent semiconductor channel layers (epitaxial layers 310), including lateral surfaces of the semiconductor channel layers, and opposing surfaces of the pair of adjacent semiconductor channel layers. In various embodiments, a selection of a particular composition of the liner layer 502 may depend on whether a convex or concave shape is desired for the metal gate profile in the final device structure. If the metal gate profile in the final device structure is to have a convex shape, the liner layer 502 may include an oxide layer 502A, also referred to as an oxide liner layer 502A, as shown in FIG. 5A. Alternatively, if the metal gate profile in the final device structure is to have a concave shape, the liner layer 502 may include a carbon-containing layer 502B (e.g., such as SiOC), also referred to a carbon-containing liner layer 502B, as shown in FIG. 5B.

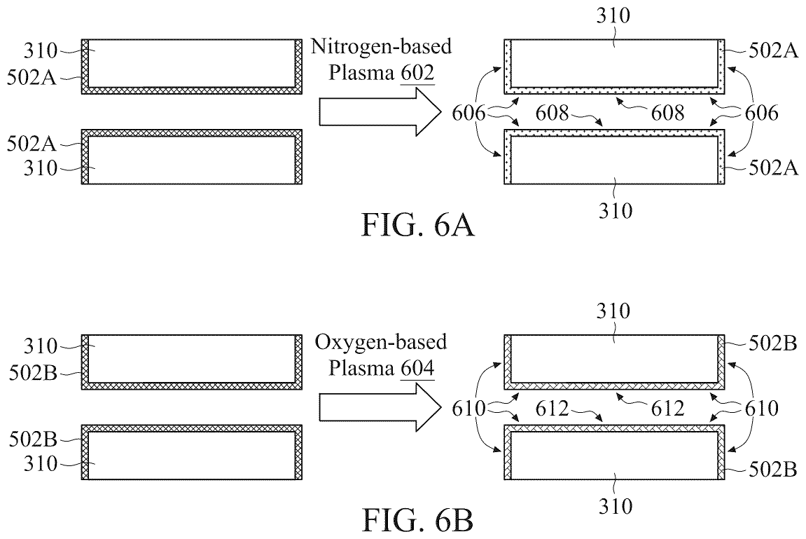

After formation of the liner layer 502 (block 208), the method 200 then proceeds to block 210 where a plasma treatment process is performed. In various embodiments, the type of plasma treatment process may depend on whether a convex or concave shape is desired for the metal gate profile in the final device structure. For instance, if the liner layer includes an oxide layer (e.g., such as in cases where the metal gate profile in the final device structure is to have a convex shape), a nitrogen-based plasma process (e.g., using NH₃ or N₂ gas) may be performed, and if the liner layer includes an SiOC layer (e.g., such as in cases where the metal gate profile in the final device structure is to have a concave shape), an oxygen-based plasma process (e.g., using O₂ gas) may be performed. In some embodiments, the plasma treatment process may include a low pressure plasma treatment. For instance, in some cases, the plasma treatment may be performed at a pressure of less than about 1 Torr. By way of example, in an embodiment of block 210, FIGS. 6A and 6B illustrate effects of the plasma treatment process on different compositions of the liner layer 502 to form a plasma-treated liner layer 502.

In particular, FIG. 6A provides the enlarged view of the portion 504 of the semiconductor device 300 including the oxide liner layer 502A (as in FIG. 5A). In this example, a nitrogen-based plasma process 602 (e.g., using NH₃ or N₂ gas) may be performed to form nitrogen-rich regions 606 within the oxide liner layer 502A on portions of the oxide liner layer 502A disposed over lateral ends (or lateral end regions) of the adjacent semiconductor channel layers (epitaxial layers 310). Formation of the nitrogen-rich regions 606 may simultaneously provide or define low nitrogen concentration regions 608 (or nitrogen-free regions 608, in some cases) of the oxide liner layer 502A disposed over central regions of the adjacent semiconductor channel layers (epitaxial layers 310). Moreover, a difference in nitrogen concentration between the nitrogen-rich regions 606, having a first nitrogen concentration, and the low nitrogen concentration regions 608 (or nitrogen-free regions 608), having a second nitrogen concentration less than the first nitrogen concentration, is sufficient to provide etch selectivity between the two regions, that is between the nitrogen-rich regions 606 and the low nitrogen concentration regions 608 (or nitrogen-free regions 608). As discussed in more detail below, during a subsequent etching process, the low nitrogen concentration regions 608 (or nitrogen-free regions 608) will be removed, while the nitrogen-rich regions 606 remain, thereby defining gaps between the adjacent semiconductor channel layers (epitaxial layers 310) within which a metal gate structure is subsequently formed, the metal gate profile of the metal gate structure having a convex shape.

FIG. 6B provides the enlarged view of the portion 504 of the semiconductor device 300 including the carbon-containing liner layer 502B (as in FIG. 5B). In this example, an oxygen-based plasma process 604 (e.g., using O₂ gas) may be performed to form carbon-deficient regions 610 within the carbon-containing liner layer 502B on portions of the carbon-containing liner layer 502B disposed over lateral ends (or lateral end regions) of the adjacent semiconductor channel layers (epitaxial layers 310). Formation of the carbon-deficient regions 610 may simultaneously define higher carbon concentration regions 612 of the carbon-containing liner layer 502B (e.g., regions of the carbon-containing liner layer 502B not substantially impacted by the oxygen-based plasma process 604) disposed over central regions of the adjacent semiconductor channel layers (cpitaxial layers 310). Moreover, a difference in carbon concentration between the carbon-deficient regions 610, having a first carbon concentration, and the higher carbon concentration regions 612, having a second carbon concentration greater than the first carbon concentration, is sufficient to provide etch selectivity between the two regions, that is between the carbon-deficient regions 610 and the higher carbon concentration regions 612. As discussed in more detail below, during a subsequent etching process, the carbon-deficient regions 610 will be removed, while the higher carbon concentration regions 612 remain, thereby defining gaps between the adjacent semiconductor channel layers (epitaxial layers 310) within which a metal gate structure is subsequently formed, the metal gate profile of the metal gate structure having a concave shape.

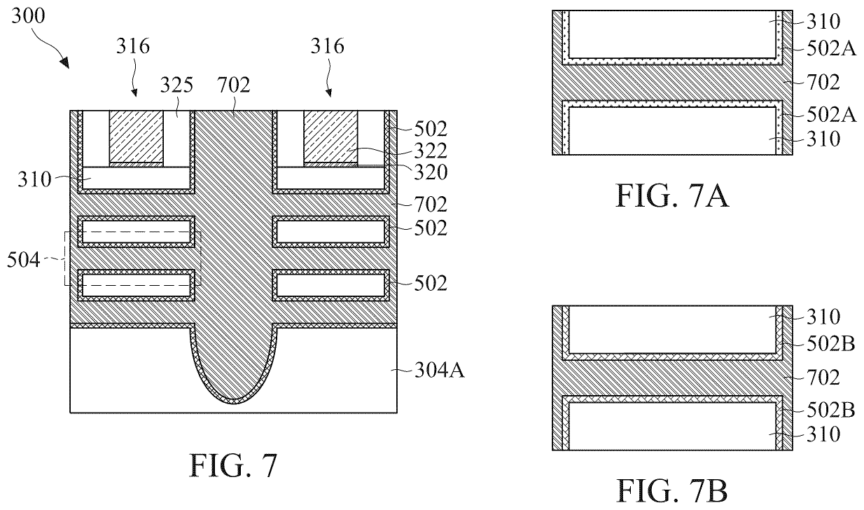

After performing the plasma treatment process (block 210), the method 200 then proceeds to block 212 where an interposer layer is deposited. Referring to FIGS. 5 and 7/7A/7B, in an embodiment of block 212, an interposer layer 702 is deposited over the device 300 and within the trench 330 over the liner layer 502. The interposer layer 702 is also deposited over the liner layer 502 within the gaps (or cavities) 402. Thus, the interposer layer 702 may be used to fill a remaining space of the gaps (or cavities) 402 formed by removal of the dummy epitaxial layers 308, as well as to fill remaining a remaining portion of the trench 330. The example of FIG. 7A provides the enlarged view of the portion 504 of the semiconductor device 300 including the oxide liner layer 502A after the nitrogen-based plasma process 602 (as in FIG. 6A), and further including the interposer layer 702. Similarly, the example of FIG. 7B provides the enlarged view of the portion 504 of the semiconductor device 300 including the carbon-containing liner layer 502B after the oxygen-based plasma process 604 (as in FIG. 6B), and further including the interposer layer 702.

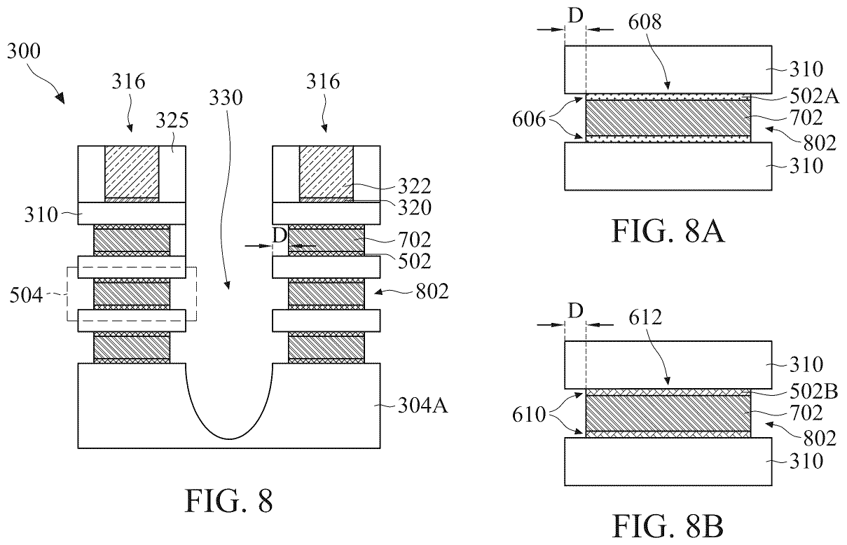

After depositing the interposer layer (block 212), the method 200 then proceeds to block 214 where the previously deposited liner layer and interposer layer are recessed. Referring to FIGS. 7/7A/7B and FIGS. 8/8A/8B, in an embodiment of block 214, a recessing process is performed to the device 300. In various examples, the recessing process etches the liner layer 502 and the interposer layer 702 from over the device 300 and from along sidewalls of the trench 330, while the liner layer 502 and the interposer layer 702 remains at least partially disposed between the adjacent semiconductor channel layers (the epitaxial layers 310). Stated another way, the recessing process of block 214 at least partially etches the liner layer 502 and the interposer layer 702 from between lateral ends of the adjacent semiconductor channel layers (the epitaxial layers 310) to form recesses 802 along sidewalls of the trench 330, for example, along lateral surfaces of the liner layer 502 and the interposer layer 702 (e.g., facing the trench 330). In various embodiments, the recesses 802 serve to define subsequently formed inner spacers, as discussed below. It is noted that after formation of the recesses 802, and for embodiments including the oxide liner layer 502A, a portion of the nitrogen-rich regions 606 remains disposed within portions of the oxide liner layer 502A disposed near lateral ends (or adjacent to lateral ends or lateral end regions) of the adjacent semiconductor channel layers (epitaxial layers 310), as shown in FIG. 8A. Similarly, after formation of the recesses 802, and for embodiments including the carbon-containing liner layer 502B, a portion of the carbon-deficient regions 610 remains disposed within portions of the carbon-containing liner layer 502B disposed near lateral ends (or adjacent to lateral ends or lateral end regions) of the adjacent semiconductor channel layers (epitaxial layers 310) as shown in FIG. 8B. By way of example, the recessing process (block 214) may be performed using a wet etch process. In some embodiments, the wet etch process may include a phosphoric acid (H₃PO₄) chemical etch of the dielectric layer 502. In some alternative examples, cycles of a high temperature sulfuric peroxide mixture (HTSPM) and dilute hydrofluoric acid (dHF), ozone (O₃) and dHF, or a combination thereof, may be used to perform the recessing process.

By way of example, the recessing process of block 214 etches the liner layer 502 and the interposer layer 702 to a nominal recess depth ‘D’ to form the recesses 802 along the sidewalls of the trench 330. While the examples of FIGS. 8/8A/8B depict the recess depth ‘D’ to be substantially equal for both the liner layer 502 and the interposer layer 702, other embodiments are possible. For instance, due to the different material composition of each of the liner layer 502 and the interposer layer 702, each of the liner layer 502 and the interposer layer 702 may have a different etch rate. The etch rate may further vary based on the particular etchant used during the recessing process. As a result, in some embodiments, the recess depth ‘D’ of the liner layer 502 may be greater than the recess depth ‘D’ of the interposer layer 702. Alternatively, in some cases, the recess depth ‘D’ of the interposer layer 702 may be greater than the recess depth of the liner layer 502. In some embodiments, a difference in the recess depths ‘D’ of each of the liner layer 502 and the interposer layer 702 may be at least 1 nm.

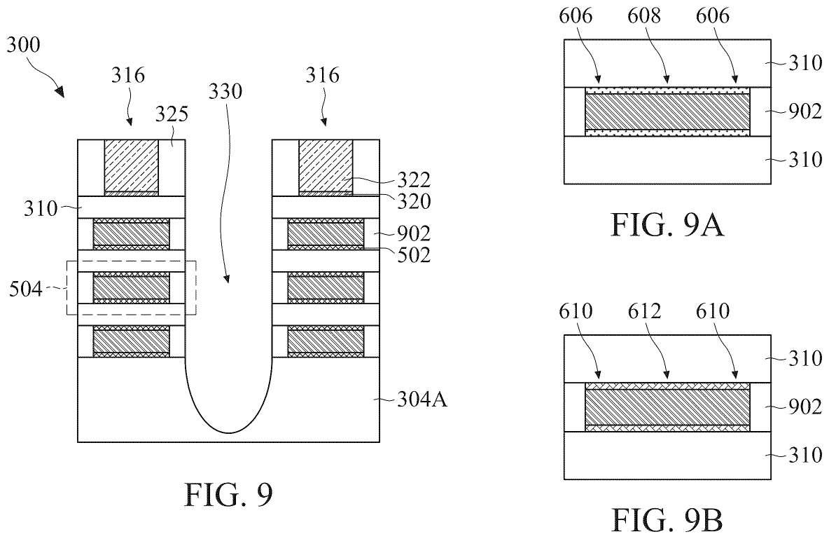

The method 200 then proceeds to block 216 where inner spacers are formed. Referring to FIGS. 8/8A/8B and FIGS. 9/9A/9B, in an embodiment of block 216, an inner spacer material is conformally deposited over the device 300, within the trenches 330 and within the recesses 802 (e.g., formed by recessing the liner layer 502 and the interposer layer 702 at block 214). In some embodiments, the inner spacer material may include amorphous silicon. In some examples, the inner spacer material may include a dielectric material such as silicon oxide, silicon nitride, silicon carbide, silicon oxynitride, SiCN, silicon oxycarbide, SiOCN, a low-K material (e.g., with a dielectric constant ‘k’<7), and/or combinations thereof. By way of example, the inner spacer material may be formed by conformally depositing the inner spacer material over the device 300 using processes such as a CVD process, a SACVD process, a flowable CVD process, an ALD process, or other suitable process. After depositing the inner spacer material, an inner spacer etch-back process is performed to etch the inner spacer material from over the device 300 and along sidewalls of the trench 330, while the inner spacer material remains disposed within the recesses 802, thereby providing inner spacers 902 for the device 300. As shown in FIGS. 9/9A/9B, the inner spacers 902 are formed in contact with the recessed liner layer 502 and the recessed interposer layer 702. In particular, as shown in FIG. 9A and for embodiments including the oxide liner layer 502A, the inner spacers 902 are formed in contact with the portion of the nitrogen-rich regions 606 of the oxide liner layer 502A near lateral ends of the adjacent semiconductor channel layers (epitaxial layers 310). Similarly, as shown in FIG. 9B and for embodiments including the carbon-containing liner layer 502B, the inner spacers 902 are formed in contact with the portion of the carbon-deficient regions 610 of the carbon-containing liner layer 502B near lateral ends of the adjacent semiconductor channel layers (epitaxial layers 310). The inner spacer etch-back process used to form the inner spacers 902 may include a wet etch process, a dry etch process, or a combination thereof. In some cases, any residual portions of the inner spacer material that remain on top surfaces of the device 300 and/or on sidewalls or bottom surfaces of the trench 330, for example after the inner spacer etch-back process, may be removed during a subsequent clean process (e.g., prior to epitaxial growth of source/drain features). In various examples, the inner spacers 902 may extend at least partially beneath the one or more spacer layers 325 formed on sidewalls of the gate stacks 316 while being disposed adjacent to subsequently formed source/drain features, as described below.

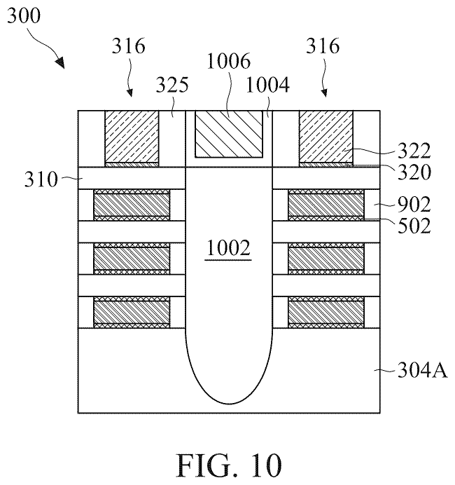

The method 200 then proceeds to block 218 where source/drain features are formed. Referring to FIGS. 9 and 10, in an embodiment of block 218 and after formation of the inner spacers 902, source/drain features are formed in the source/drain regions adjacent to and on either side of the gate stacks 316 of the device 300. For example, a source/drain feature 1002 may be formed within the trench 330 of the device 300, over the exposed portions of the substrate 304 and in contact with the adjacent inner spacers 902 and the semiconductor channel layers (the epitaxial layers 310) of the device 300. In some embodiments, a clean process may be performed immediately prior to formation of the source/drain features 1002 to remove any residual portions of inner spacer material, as previously noted. The clean process may include a wet etch, a dry etch, or a combination thereof.

In some embodiments, the source/drain features 1002 are formed by epitaxially growing a semiconductor material layer in the source/drain regions. In various embodiments, the semiconductor material layer grown to form the source/drain features 1002 may include Ge, Si, GaAs, AlGaAs, SiGe, GaAsP, SiP, or other suitable material. The source/drain features 1002 may be formed by one or more epitaxial (epi) processes. In some embodiments, the source/drain features 1002 may be in-situ doped during the epi process. For example, in some embodiments, epitaxially grown SiGe source/drain features may be doped with boron. In some cases, epitaxially grown Si epi source/drain features may be doped with carbon to form Si: C source/drain features, phosphorous to form Si: P source/drain features, or both carbon and phosphorous to form SiCP source/drain features. In some embodiments, the source/drain features 1002 are not in-situ doped, and instead an implantation process is performed to dope the source/drain features 1002.

After forming the source/drain features 1002, and in some embodiments, a contact etch stop layer (CESL) 1004 may be conformally formed over the device 300, as shown in FIG. 10. In some examples, the CESL 1004 may include a silicon nitride layer, silicon oxide layer, a silicon oxynitride layer, and/or other materials known in the art. In some embodiments, an inter-layer dielectric (ILD) layer 1006 may be formed over the CESL 1004, as also shown in FIG. 10. In various cases, the ILD layer 1006 may include materials such as tetraethylorthosilicate (TEOS) oxide, undoped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. In some embodiments, after formation of the ILD layer 1006, the device 300 may be subject to a high thermal budget process to anneal the ILD layer 1006. In some embodiments, after formation of the CESL 1004 and the ILD layer 1006, a chemical mechanical polishing (CMP) process may be performed to remove portions of the ILD layer 1004 and the CESL 1006 overlying the gate stacks 316, as well as any hard mask layers that may be present over the gate stacks 316, to planarize a top surface of the device 300 and expose a top surface of the electrode layer 322 of the gate stacks 316.

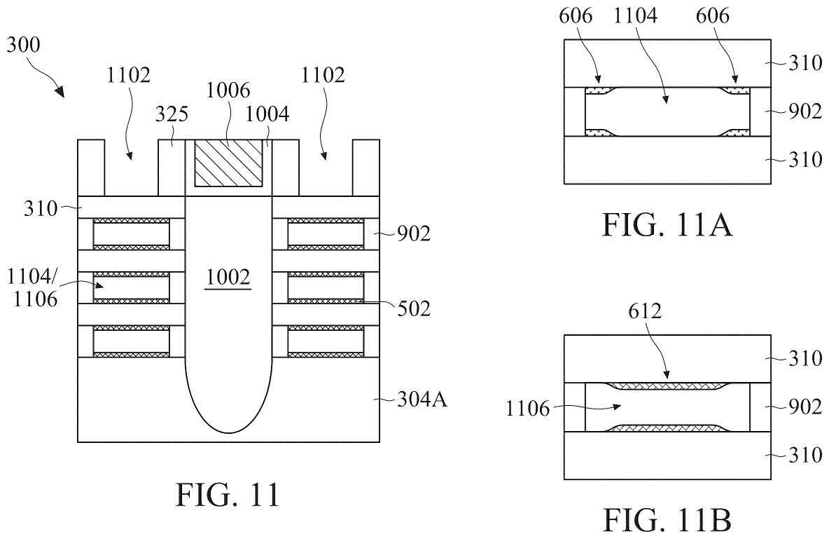

The method 200 then proceeds to block 220 where the interposer layer is removed. Referring to the example of FIGS. 10 and 11/11A/11B, in an embodiment of block 220, the electrode layer 322 of the gate stacks 316 (e.g., exposed by the CMP process, as noted above) may initially be removed by suitable etching processes to form trenches 1102 that expose the dielectric layer 320 of the gate stacks 316. Thereafter, in some embodiments, an etching process may be performed to remove the exposed dielectric layer 320 from the trenches 1102. In some examples, the etching processes used to remove the electrode layer 322 and the dielectric layer 320 may include a wet etch, a dry etch, or a combination thereof. It is noted that removal of the electrode layer 322 and the dielectric layer 320 provides for removal of the dummy gates (gate stacks 316), for example, as part of a replacement gate process.

Still referring to the example of FIGS. 10 and 11/11A/11B, in a further embodiment of block 220 and after removal of the electrode layer 322 and the dielectric layer 320, the portions of the interposer layer 702 that remain disposed between adjacent semiconductor channel layers (the epitaxial layers 310) in the channel region of the device 300 are removed (e.g., such as by using a wet etching process), while the semiconductor channel layers (the epitaxial layers 310) and the inner spacers 902 remain substantially unetched. The etching process may be performed through the trenches 1102 provided by the removal of the electrode layer 322 and the dielectric layer 320. Additionally, in various embodiments, removal of the interposer layer 702 will also remove selected portions of the liner layer 502.

For example, in embodiments including the oxide liner layer 502A treated using the nitrogen-based plasma process 602, removal of the portions of the interposer layer 702 also serves to remove the low nitrogen concentration regions 608 (or nitrogen-free regions 608) of the oxide liner layer 502A, while the nitrogen-rich regions 606 of the oxide liner layer 502A remain disposed over lateral end regions of the adjacent semiconductor channel layers (as in FIG. 11A), due to the etch selectivity between the nitrogen-rich regions 606 and the low nitrogen concentration regions 608 (or nitrogen-free regions 608) of the oxide liner layer 502A. The nitrogen-rich regions 606 of the oxide liner layer 502A that remain, together with the adjacent semiconductor channel layers (epitaxial layers 310), serve to define a gap 1104 between the adjacent semiconductor channel layers having a concave shape. As shown, the gap 1104 exposes a first portion of the epitaxial layers 310, while a second portion of the epitaxial layers 310 on either side of the first portion is covered by the nitrogen-rich regions 606 of the oxide liner layer 502A, and while a third portion of the epitaxial layers 310 remains covered by the inner spacers 902. The gap 1104 also exposes a sidewall of the inner spacers 902 on opposing sides of the gap 1104. In some embodiments, a metal gate structure subsequently be formed within the gap 1104, as discussed below, will have a metal gate profile with a convex shape that is complementary to the concave shape of the gap 1104.

Alternatively, in embodiments including the carbon-containing liner layer 502B treated using the oxygen-based plasma process 604, removal of the portions of the interposer layer 702 also serves to remove the carbon-deficient regions 610 of the carbon-containing liner layer 502B, while the higher carbon concentration regions 612 of the carbon-containing liner layer 502B remain disposed over central regions of the adjacent semiconductor channel layers (as in FIG. 11B), due to the etch selectivity between the carbon-deficient regions 610 and the higher carbon concentration regions 612 of the carbon-containing liner layer 502B. The higher carbon concentration regions 612 of the carbon-containing liner layer 502B that remain, together with the adjacent semiconductor channel layers (epitaxial layers 310), serve to define a gap 1106 between the adjacent semiconductor channel layers having a convex shape. As shown, a first portion of the epitaxial layers 310 remains covered by the higher carbon concentration regions 612 of the carbon-containing liner layer 502B, while the gap 1106 exposes second portions of the epitaxial layers 310 on either side of the first portion, and while a third portion of the epitaxial layers 310 remains covered by the inner spacers 902. The gap 1106 also exposes a sidewall of the inner spacers 902 on opposing sides of the gap 1106. In some embodiments, a metal gate structure subsequently be formed within the gap 1106, as discussed below, will have a metal gate profile with a concave shape that is complementary to the convex shape of the gap 1106.

In some cases, the etching process of block 220 may include a wet etching process, as described above. Further, in some embodiments, the etching process of block 220 may be performed using ammonia (NH₃) and/or ozone (O₃). In another example, the etching process may be performed using tetra-methyl ammonium hydroxide (TMAH). In some embodiments, the etching process may include a dry, plasma-free etching process. In some examples, the etching process may include etching using a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

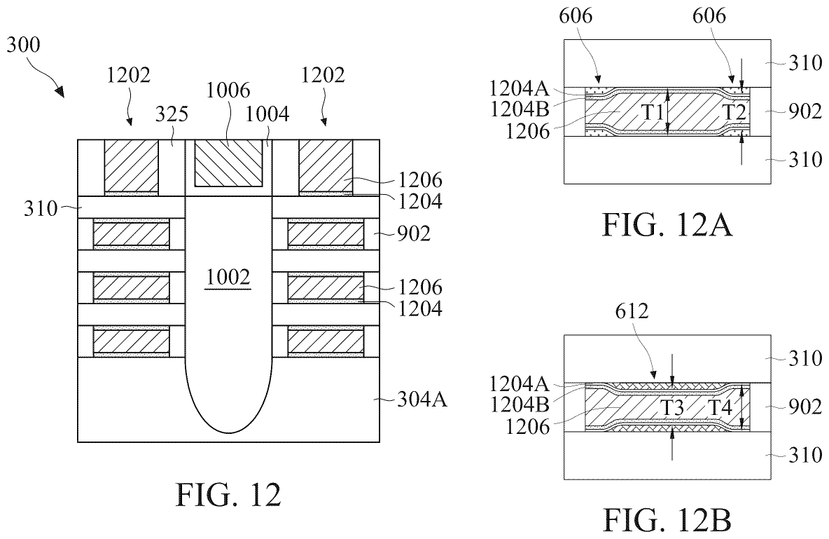

The method 200 then proceeds to block 222 where a gate structure is formed. Referring to the example of FIGS. 11/11A/11B, 12/12A/12B, 13A/13B, and 14A/14B, in an embodiment of block 222, final gate structures 1202 for the device 300 are formed. The gate structures 1202 may include a high-K/metal gate stack, however other compositions are possible. In some embodiments, the gate structures 1202 may form the gate associated with the multi-channels provided by the plurality of semiconductor channel layers (the epitaxial layers 310) in the channel region of the device 300. In some embodiments, the gate structures 1202 include a dielectric layer 1204 composed of an interfacial layer (IL) 1204A and a high-K dielectric layer 1204B formed over the IL 1204A. In various embodiments, the IL 1204A and the high-K dielectric layer 1204B collectively define a gate dielectric of the gate structure for the device 300. In some embodiments, the gate dielectric has a total thickness of about 1-5 nm. High-K gate dielectrics, as used and described herein, include dielectric materials having a high dielectric constant, for example, greater than that of thermal silicon oxide (˜3.9). Generally, the gate dielectric may be formed on various surfaces of the gaps 1104, 1106. In some embodiments, as shown in FIG. 12A, the IL 1204A and the high-K dielectric layer 1204B may be deposited over exposed surfaces of the epitaxial layers 310 and the nitrogen-rich regions 606 of the oxide liner layer 502A. Similarly, in some embodiments and as shown in FIG. 12B, the IL 1204A and the high-K dielectric layer 1204B may be deposited over exposed surfaces of the epitaxial layers 310 and the higher carbon concentration regions 612 of the carbon-containing liner layer 502B. In the embodiments of FIG. 12A and FIG. 12B, the IL 1204A may be deposited by a CVD process, providing for deposition over the nitrogen-rich regions 606 or the higher carbon concentration regions 612. In some cases, the dielectric layer 1204, including the IL 1204A and/or the high-K dielectric layer 1204B, may also be deposited on sidewall surfaces of the inner spacers 902.

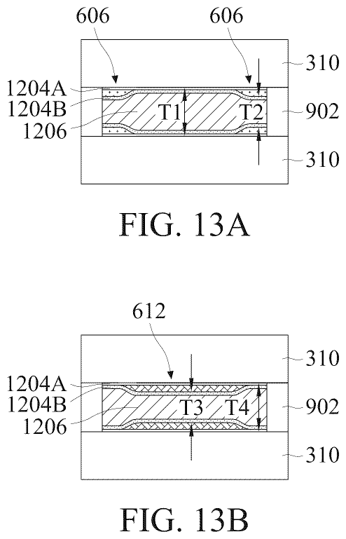

In other embodiments, as shown in FIG. 13A, the IL 1204A is initially formed by oxidation of surfaces of the epitaxial layers 310. For portions of the epitaxial layers 310 not covered by the nitrogen-rich regions 606, and during formation of the IL 1204A, the IL 1204A may be readily formed on the exposed surface of the epitaxial layers 310. For the portions of the epitaxial layers 310 covered by the nitrogen-rich regions 606, and during formation of the IL 1204A, oxidants may diffuse through the nitrogen-rich regions 606 to form the IL 1204A at the interface between the epitaxial layers 310 and the nitrogen-rich regions 606. As a result, the IL 1204A may be formed along an entire surface of the epitaxial layers 310 between the inner spacers 902. Thereafter, the high-K dielectric layer 1204B may be deposited over the nitrogen-rich regions 606 and over the IL 1204A that was formed on the exposed surface of the epitaxial layers 310 (regions not covered by the nitrogen-rich regions 606). In the embodiment of FIG. 13A, and duc to forming the IL 1204A at the interface between the epitaxial layers 310 and the nitrogen-rich regions 606 by diffusion of oxidants through the nitrogen-rich regions 606, the IL 1204A disposed at the interface between the epitaxial layers 310 and the nitrogen-rich regions 606 may have a different thickness (e.g., thinner, in some cases) as compared to the IL 1204A disposed over the exposed surface of the epitaxial layers 310 (regions not covered by the nitrogen-rich regions 606). Similarly, in some embodiments and as shown in FIG. 13B, the IL 1204A is initially formed by oxidation of surfaces of the epitaxial layers 310. For portions of the epitaxial layers 310 not covered by the higher carbon concentration regions 612, and during formation of the IL 1204A, the IL 1204A may be readily formed on the exposed surface of the epitaxial layers 310. For the portions of the epitaxial layers 310 covered by the higher carbon concentration regions 612, and during formation of the IL 1204A, oxidants may diffuse through the higher carbon concentration regions 612 to form the IL 1204A at the interface between the epitaxial layers 310 and the higher carbon concentration regions 612. As a result, the IL 1204A may be formed along an entire surface of the epitaxial layers 310 between the inner spacers 902. Thereafter, the high-K dielectric layer 1204B may be deposited over the higher carbon concentration regions 612 and over the IL 1204A that was formed on the exposed surface of the epitaxial layers 310 (regions not covered by the higher carbon concentration regions 612). In the embodiment of FIG. 13B, and due to forming the IL 1204A at the interface between the epitaxial layers 310 and the higher carbon concentration regions 612 by diffusion of oxidants through the higher carbon concentration regions 612, the IL 1204A disposed at the interface between the epitaxial layers 310 and the higher carbon concentration regions 612 may have a different thickness (e.g., thinner, in some cases) as compared to the IL 1204A disposed over the exposed surface of the epitaxial layers 310 (regions not covered by the higher carbon concentration regions 612).

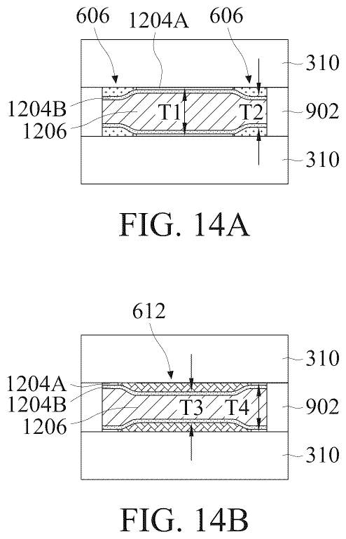

In still other embodiments, as shown in FIG. 14A, the IL 1204A is initially formed over portions of the epitaxial layers 310 not covered by the nitrogen-rich regions 606, but not over portions of the epitaxial layers 310 covered by the nitrogen-rich regions 606. Thereafter, the high-K dielectric layer 1204B may be deposited over the nitrogen-rich regions 606 and over the IL 1204A that was formed on the exposed surface of the epitaxial layers 310 (regions not covered by the nitrogen-rich regions 606). Similarly, in some embodiments and as shown in FIG. 14B, the IL 1204A is initially formed over portions of the epitaxial layers 310 not covered by the higher carbon concentration regions 612, but not over portions of the epitaxial layers 310 covered by the higher carbon concentration regions 612 Thereafter, the high-K dielectric layer 1204B may be deposited over the higher carbon concentration regions 612 and over the IL 1204A that was formed on the exposed surface of the epitaxial layers 310 (regions not covered by the higher carbon concentration regions 612).

In some embodiments, the IL may include a dielectric material such as silicon oxide (SiO₂), HfSiO, or silicon oxynitride (SiON). In some examples, the high-K dielectric layer may include hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. Unless stated otherwise in the above discussion, and in various embodiments, the IL 1204A and the high-K dielectric layer 1204B may be formed by thermal oxidation, ALD, physical vapor deposition (PVD), pulsed laser deposition (PLD), CVD, and/or other suitable methods.

Still referring to the examples of FIGS. 11/11A/11B, 12/12A/12B, 13A/13B, and 14A/14B, a metal gate including a metal layer 1206 is formed over the gate dielectric (e.g., over the IL and the high-K dielectric layer). The metal layer 1206 may include a metal, metal alloy, or metal silicide. Additionally, the formation of the gate dielectric/metal gate stack may include depositions to form various gate materials, one or more liner layers, and one or more CMP processes to remove excessive gate materials and thereby planarize a top surface of the device 300.

In some embodiments, the metal layer 1206 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer 1206 may include Ti, Ag, Al, TiAlN, TaC, TaCN, TaSlN, Mn, Zr, TiN, TaN, Ru, Mo, Al, WN, Cu, W, Re, Ir, Co, Ni, other suitable metal materials or a combination thereof. In various embodiments, the metal layer 1206 may be formed by ALD, PVD, CVD, e-beam evaporation, or other suitable process. Further, the metal layer 1206 may be formed separately for N-type and P-type transistors which may use different metal layers. In addition, the metal layer 1206 may provide an N-type or P-type work function, may serve as a transistor (e.g., GAA transistor) gate electrode, and in at least some embodiments, the metal layer 1206 may include a polysilicon layer. With respect to the devices shown and discussed, the gate structure includes portions that interpose each of the epitaxial layers 310, which each provide semiconductor channel layers for the GAA transistors.

Thus, as shown in FIG. 12A/13A/14A, the portion of the gate structure 1202 (including the dielectric layer 1204 and the metal layer 1206) formed in the gap 1104 between adjacent semiconductor channel layers (epitaxial layers 310) has a metal gate profile with a convex shape that is complementary to the concave shape of the gap 1104 within which it is disposed. For example, the metal gate profile with the convex shape may have a thickness T1 near a center of the portion of the gate structure 1202 disposed between center regions of the adjacent semiconductor channel layers (adjacent epitaxial layers 310), where the thickness T1 is greater than a thickness T2 near lateral ends of the portion of the gate structure 1202 disposed between lateral ends of the adjacent semiconductor channel layers (adjacent epitaxial layers 310). Similarly, as shown in FIG. 12B/13B/14B, the portion of the gate structure 1202 (including the dielectric layer 1204 and the metal layer 1206) formed in the gap 1106 between adjacent semiconductor channel layers (epitaxial layers 310) has a metal gate profile with a concave shape that is complementary to the convex shape of the gap 1106 within which it is disposed. For example, the metal gate profile with the concave shape may have a thickness T3 near a center of the portion of the gate structure 1202 disposed between center regions of the adjacent semiconductor channel layers (adjacent epitaxial layers 310), where the thickness T3 is less than a thickness T4 near lateral ends of the portion of the gate structure 1202 disposed between lateral ends of the adjacent semiconductor channel layers (adjacent epitaxial layers 310). In some embodiments, the thickness T1 may be substantially the same as the thickness T4. It is also noted that while the liner layer 502 is not specifically shown in FIG. 12 for case of illustration, the nitrogen-rich regions 606 of the oxide liner layer 502A and the higher carbon concentration regions 612 of the carbon-containing liner layer 502B are present, as shown in FIGS. 12A/13A/14A and 12B/13B/14B, respectively.

Generally, the semiconductor device 300 may undergo further processing to form various features and regions known in the art. For example, further processing may form various contacts/vias/lines and multilayer interconnect features (e.g., metal layers and interlayer dielectrics) on the substrate 304, configured to connect the various features to form a functional circuit that may include one or more multi-gate devices (e.g., one or more GAA transistors). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be modified, replaced, or eliminated in accordance with various embodiments of the method 200.

With respect to the description provided herein, disclosed are methods and structures for modulating a metal gate profile of a multi-gate device (e.g., such as a GAA device). In various embodiments, the metal gate profile (e.g., between adjacent semiconductor channel layers) in a final device structure may have a convex shape or a concave shape. In some examples, a method of modulating the metal gate profile includes initially removing dummy layers (e.g., such as SiGe layers) that interpose adjacent semiconductor channel layers and re-depositing a liner layer and an interposer layer to fill a cavity formed by removal of the dummy layers. The liner layer includes an oxide layer, a carbon-containing layer, or other suitable layer, and the selection of a particular composition of the liner layer may depend on the desired metal gate profile in the final device structure. After depositing the liner layer, and prior to depositing the interposer layer, a plasma process may be performed to treat the liner layer (e.g., using a nitrogen-based plasma if the liner layer includes an oxide layer, or using an oxygen-based plasma if the liner layer includes a carbon-containing layer). After performing the plasma treatment of the liner layer, the interposer layer may be deposited to fill the remaining space of the cavity. During subsequent processing, remaining portions of the interposer layer, as well as selected portions of the plasma-treated liner layer, are removed to form gaps between adjacent semiconductor channel layers within which a metal gate structure is formed. For example, if the liner layer includes an oxide layer, removal of the portions of the interposer layer also removes low nitrogen concentration regions (or nitrogen-free regions) of the oxide liner layer, while nitrogen-rich regions of the oxide liner layer remain disposed over lateral end regions of the adjacent semiconductor channel layers. The nitrogen-rich regions of the oxide liner layer that remain, together with the adjacent semiconductor channel layers, serve to define a gap between the adjacent semiconductor channel layers having a concave shape. A metal gate structure may thus subsequently be formed within the gap, where the metal gate profile of the metal gate structure has a convex shape that is complementary to the concave shape of the gap. Alternatively, if the liner layer includes a carbon-containing layer, removal of the portions of the interposer layer also removes carbon-deficient regions of the carbon-containing liner layer, while higher carbon concentration regions of the carbon-containing liner layer remain disposed over central regions of the adjacent semiconductor channel layers. The higher carbon concentration regions of the carbon-containing liner layer that remain, together with the adjacent semiconductor channel layers, serve to define a gap between the adjacent semiconductor channel layers having a convex shape. A metal gate structure may thus subsequently be formed within the gap, where the metal gate profile of the metal gate structure has a concave shape that is complementary to the convex shape of the gap. Embodiments of the present disclosure thus provide effective control of a metal gate profile implemented as part of a disposable interposer process, which can be tuned in accordance with device design and/or performance requirements.

Thus, one of the embodiments of the present disclosure described a method that includes providing a fin having an epitaxial layer stack with a plurality of semiconductor channel layers interposed by a plurality of dummy layers. In some embodiments, the method further includes removing the plurality of dummy layers to form a first gap between adjacent semiconductor channel layers of the plurality of semiconductor channel layers. In some examples, the method further includes depositing a liner layer over surfaces of the adjacent semiconductor channel layers exposed by the first gap. In some embodiments, the method further includes performing a plasma treatment process to the liner layer to provide a plasma-treated liner layer. In some cases, the method further includes removing a first portion of the plasma-treated liner layer to form a second gap between the adjacent semiconductor channel layers, while a second portion of the plasma-treated liner layer remains disposed on surfaces of the adjacent semiconductor channel layers.

In another of the embodiments, discussed is a method that includes providing a fin having an epitaxial layer defining a semiconductor channel layer and surrounding an exposed surface of the epitaxial layer with a liner layer. In some examples, the method further includes performing a plasma treatment process to the liner layer to define a first region of the liner layer disposed over a first portion of the epitaxial layer and second region of the liner layer disposed over a second portion of the epitaxial layer. In some embodiments, the method further includes removing the first region of the liner layer to form a gap between the epitaxial layer and an adjacent epitaxial layer defining an adjacent semiconductor channel layer, while a second region of the liner layer remains disposed over the second portion of the epitaxial layer. In some cases, the method further includes forming a portion of a metal gate structure within the gap, where a metal gate profile of the portion of the metal gate structure has a convex shape or a concave shape.

In yet another of the embodiments, discussed is a semiconductor device including a plurality of semiconductor channel layers formed over a substrate. In some embodiments, the semiconductor device further includes inner spacers disposed between adjacent semiconductor channel layers of the plurality of semiconductor channel layers and on either side of a channel region. In some examples, the semiconductor device further includes a metal gate structure disposed between the adjacent semiconductor channel layers, where the inner spacers are disposed on either side of the metal gate structure, and where a liner layer is disposed between part of the metal gate structure and each of the adjacent semiconductor channel layers. In some embodiments, a metal gate profile of the metal gate structure has a convex shape or a concave shape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a fin including an epitaxial layer stack having a plurality of semiconductor channel layers interposed by a plurality of dummy layers;
removing the plurality of dummy layers to form a first gap between adjacent semiconductor channel layers of the plurality of semiconductor channel layers;
depositing a liner layer over surfaces of the adjacent semiconductor channel layers exposed by the first gap;
performing a plasma treatment process to the liner layer to provide a plasma-treated liner layer; and
removing a first portion of the plasma-treated liner layer to form a second gap between the adjacent semiconductor channel layers, while a second portion of the plasma-treated liner layer remains disposed on surfaces of the adjacent semiconductor channel layers.

2. The method of claim 1, wherein the liner layer includes an oxide layer, and wherein the plasma treatment process includes a nitrogen-based plasma process.

3. The method of claim 1, wherein the liner layer includes carbon-containing layer, and wherein the plasma treatment process includes an oxygen-based plasma process.

4. The method of claim 1, wherein the first portion of the plasma-treated liner layer includes an oxide layer having a first nitrogen concentration, and wherein the second portion of the plasma-treated liner layer includes the oxide layer having a second nitrogen concentration greater than the first nitrogen concentration.

5. The method of claim 1, wherein the first portion of the plasma-treated liner layer includes a carbon-containing layer having a first carbon concentration, and wherein the second portion of the plasma-treated liner layer includes the carbon-containing layer having a second carbon concentration greater than the first carbon concentration.

6. The method of claim 1, wherein the second portion of the plasma-treated layer that remains disposed on surfaces of the adjacent semiconductor channel layers, together with the adjacent semiconductor channel layers, serve to define the second gap between the adjacent semiconductor channel layers, and wherein the second gap has a concave shape.

7. The method of claim 1, wherein the second portion of the plasma-treated layer that remains disposed on surfaces of the adjacent semiconductor channel layers, together with the adjacent semiconductor channel layers, serve to define the second gap between the adjacent semiconductor channel layers, and wherein the second gap has a convex shape.

8. The method of claim 1, further comprising:
after performing the plasma treatment process and prior to removing the first portion of the plasma-treated liner layer, forming an interposer layer over the liner layer within the first gap, wherein the interposer layer serves to substantially fill remaining portions of the first gap; and
after forming inner spacers, removing the interposer layer, wherein the removing the interposer layer also removes the first portion of the plasma-treated liner layer.

9. The method of claim 8, further comprising:
prior to forming the inner spacers, etching lateral ends of the liner layer and the interposer layer, wherein the etching the lateral ends recesses the lateral ends of the liner layer to a first depth and recesses the lateral ends of the interposer layer to a second depth different than the first depth.

10. The method of claim 6, further comprising:
after removing the first portion of the plasma-treated liner layer, forming a portion of a gate structure within the second gap, wherein the portion of the gate structure has a convex shape that is complementary to the concave shape of the second gap.

11. A method of fabricating a semiconductor device, comprising:
providing a fin including an epitaxial layer defining a semiconductor channel layer;
surrounding an exposed surface of the epitaxial layer with a liner layer;
performing a plasma treatment process to the liner layer to define a first region of the liner layer disposed over a first portion of the epitaxial layer and second region of the liner layer disposed over a second portion of the epitaxial layer;
removing the first region of the liner layer to form a gap between the epitaxial layer and an adjacent epitaxial layer defining an adjacent semiconductor channel layer, while a second region of the liner layer remains disposed over the second portion of the epitaxial layer; and
forming a portion of a metal gate structure within the gap, wherein a metal gate profile of the portion of the metal gate structure has a convex shape or a concave shape.

12. The method of claim 11, wherein the liner layer includes an oxide layer, and wherein the plasma treatment process includes a nitrogen-based plasma process.

13. The method of claim 11, wherein the liner layer includes carbon-containing layer, and wherein the plasma treatment process includes an oxygen-based plasma process.

14. The method of claim 11, wherein the first region of the liner layer includes an oxide layer having a first nitrogen concentration, and wherein the second region of the liner layer includes the oxide layer having a second nitrogen concentration greater than the first nitrogen concentration.

15. The method of claim 11, wherein the first region of the liner layer includes a carbon-containing layer having a first carbon concentration, and wherein the second region of the liner layer includes the carbon-containing layer having a second carbon concentration greater than the first carbon concentration.

16. The method of claim 14, wherein second region of the liner layer includes a nitrogen-rich region of the oxide layer.

17. The method of claim 15, wherein first region of the liner layer includes a carbon-deficient region of the carbon-containing layer.

18. A semiconductor device, comprising:
a plurality of semiconductor channel layers formed above a substrate;
inner spacers disposed between adjacent semiconductor channel layers of the plurality of semiconductor channel layers and on either side of a channel region; and
a metal gate structure disposed between the adjacent semiconductor channel layers, wherein the inner spacers are disposed on either side of the metal gate structure, and wherein a liner layer is disposed between part of the metal gate structure and each of the adjacent semiconductor channel layers;
wherein a metal gate profile of the metal gate structure has a convex shape or a concave shape.

19. The semiconductor device of claim 18, wherein when the metal gate profile has the convex shape, the metal gate structure has a first thickness near a center portion of the metal gate structure disposed between center regions of the adjacent semiconductor channel layers, the first thickness greater than a second thickness of the metal gate structure near lateral ends of the metal gate structure disposed between lateral ends of the adjacent semiconductor channel layers.

20. The semiconductor device of claim 18, wherein when the metal gate profile has the concave shape, the metal gate structure has a first thickness near a center portion of the metal gate structure disposed between center regions of the adjacent semiconductor channel layers, the first thickness less than a second thickness of the metal gate structure near lateral ends of the metal gate structure disposed between lateral ends of the adjacent semiconductor channel layers.
